(19) United States
(12) Patent Application Publication
(10) Pub. No.: US 2010/0132305 A1
(43) Pub. Date: Jun. 3, 2010

(54) Method and system for providing and installing photovoltaic material

(76) Inventors: Steve Heckeroth, Albion, CA (US); Daniel M. Perkins, Ishpeming, MI (US); Howard Letovsky, Willits, CA (US)

Correspondence Address: STEVE HECKEROTH, 30151 NAVARRO RIDGE ROAD, ALBION, CA, 95410, US

(21) Appl. No.: 12/587,455

(22) Filed: Oct. 6, 2009

(51) Int. Cl. E04B 1/38; H01L 31/042

(52) U.S. Cl. 52/745.21; 136/244

(57) ABSTRACT

The present invention discloses a flexible building integrated photovoltaic energy absorbing system and method that comprise variable length photovoltaic strips which can be applied to a surface of a building at any pitch or angle. Further, the present invention may include electrical connection members that can be easily attached to said photovoltaic strips at any point on their surface such that said photovoltaic strips can be connected in series, parallel, series parallel, or any other electrical combination, and that said electrical connection members may terminate at a location on said surface of any pitch or angle that is easily serviced, made weatherproof, and can be finished covered in an aesthetically pleasing manner.

### FIELD OF THE INVENTION

One or more embodiments of the present disclosure relate to a method and system for providing and installing a photovoltaic (PV) material onto the surface of a building.

### BACKGROUND ART

Early renewable energy installations, including PV, were used to power remote facilities when the cost of extending utility service was not practical. These types of renewable energy installations are generally referred to as off-grid and may include batteries to provide power when renewable energy is not available.

Batteries are typically available in nominal 12 volt, direct current (DC) increments and must be charged at a DC voltage that is slightly higher than this nominal DC voltage. For this reason a specific number of PV cells were electrically connected in series and encapsulated into a module.

Within the last several years, governments and consumers have begun to recognize the benefits of increased renewable energy production to reduce dependence on finite energy resources; and reduce the environmentally harmful by-products of combustion (e.g., carbon dioxide).

Some governments have begun to offer energy rebates, tax credits and supplemental payments for renewable energy production called feed-in-tariffs (FITs). These incentives have popularized a new type of renewable energy installation that interacts with the power from the utility grid.

These new utility connected renewable energy installations are called grid-tie systems. Grid-tie renewable energy systems do not need to produce battery charging DC voltage but are instead produce alternating current (AC) that synchronizes with utility power.

The component that changes the DC power available from a series of electrically connected PV cells into the AC power that synchronizes with the grid is called an inverter. Recent developments in inverter technology and other grid-tie and off-grid renewable energy system components make it possible for a wide range of DC voltages to be inverted to match the waveform of AC voltage required by the grid and household appliances. These recent developments in renewable energy system components allow a very large range of DC voltage inputs to be produced and remove the battery charging voltage limitations on the number of PV cells that can be electrically connected in series to make a PV module. The usability of variable sized and variable voltage PV modules combined with the development of low cost efficient flexible thin-film PV cells that can be integrated into roofing and siding materials make the present invention possible.

Most buildings are exposed to thousands of hours of direct solar radiation annually and have enough surface area bathed in sunlight to satisfy the power needs of their occupants even if just a fraction of their surface area is covered with PV. Building integrated photovoltaics (BIPV) have many advantages over utility scale ground mount PV installations. BIPV uses wasted roof and wall area to generate power where it is used. Utility scale ground mount PV installations cover valuable land and require transmission and distribution infrastructure. BIPV offsets building materials and construction costs and is secure from theft and vandalism. Utility ground mount requires a costly permitting process and security infrastructure. Power from BIPV is valued at the high retail rate. Power from utility ground mount is valued at the low wholesale rate.

Even with government incentives, the rising cost of conventional power and the mounting evidence of the irreversible damage done by continued fossil fuel combustion, a very small percentage of consumers have so far been willing to install renewable energy systems. The high initial investment and the perceived objectionable aesthetic of PV modules are the reasons most often given for not installing a PV system.

Potential consumers are demanding affordable PV products that can be installed upon a buildings surface in an aesthetically pleasing manner and have a warrantee period that is equal to other roofing and siding products. Furthermore, contractors realize that in addition to being aesthetically pleasing, a photovoltaic building material must meet all of the requirements of conventional roofing and siding products including ease of installation, weather tightness, fire resistance, and compliance with local codes and conventions.

In order to attempt to satisfy the market demand, PV manufacturers have begun to develop and offer thin and flexible PV cells. Unfortunately, the finished thin and flexible PV products are currently only available in a few specific sizes and must be bonded over traditional roofing products. Furthermore, the installation cost of the PV products currently available requires a substantial investment by the consumer.

The most relevant prior art currently in commerce is reflected in the U.S. Pat. Nos. 6,730,841 and 6,729,081, both which are associated with Steve Heckeroth, the first named inventor of the present invention.

### SUMMARY OF THE PRESENT INVENTION

The method and system disclosed herein include structure covering, roofing and/or siding strips that may incorporate thin and flexible photovoltaic (PV) cells connected in series strings which can be cut or manufactured to any length to cover a surface of a structure at any pitch or angle. Further, said PV strips may include electrically active contact points at any point on their surface which may provide direct connection capabilities between adjacent PV strips.

The present invention may also provide electrical connection clamp and electrical wiring members that can be easily attached to said electrically active contact points on said photovoltaic strips such that said photovoltaic strips can be connected in series, parallel, series parallel, or to combiner box, or battery, or power conditioning equipment, and that said electrical connection members may terminate at a location on said surface of any pitch or angle that is easily serviced, made weatherproof, and can be finished covered in an aesthetically pleasing manner.

### BRIEF DESCRIPTION OF THE DRAWINGS

FIG. 1 shows a cross section through a strip of flexible thin-film PV cells connected in series.

FIG. 1a shows a cross section through a strip of flexible thin-film PV cells connected in series with bypass diodes incorporated in parallel

FIG. 2 shows a top plan view of a photovoltaic strip in accordance with one or more embodiments of the present disclosure;

FIG. 2a shows another top plan view of the photovoltaic strip depicted in FIG. 2a;

FIG. 2b shows another top plan view of photovoltaic strip depicted in FIG. 2a;

FIG. 3 illustrates a factory installed termination cover.

FIG. 3a illustrates a cross section through a gable end soffit showing the connection of factory installed terminations.

FIG. 3b illustrates a top plan view of a plurality of photovoltaic strips about the gable end portion of a roof depicted in FIG. 3a;

FIG. 3c illustrates a top plan view of a plurality of photovoltaic roofing strips about a hip portion of a roof showing the connection of factory installed terminations.

FIG. 4 shows a plan view of a strip of flexible thin-film PV cells with a negative buss bar.

FIG. 4a shows a plan view of a PV strip depicted in FIG. 4 after a strip of PV cells has been cut with on-site installed wiring clamp connections completed.

FIG. 5 shows a plan view of a strip of flexible thin-film PV cells with negative and positive buss bars.

FIG. 5a shows a plan view as depicted in FIG. 5 after a strip of PV cells has been cut with on-site installed wiring clamp connections completed.

FIG. 6 illustrates a pair of PV strips in accordance with one or more embodiments of the present disclosure;

FIG. 6a is a cross-sectional view of the PV strips depicted in FIG. 6

FIG. 7 illustrates a pair of PV strips in accordance with one or more embodiments of the present disclosure specifically depicting continuous electrical contact elements;

FIG. 7a is a cross-sectional view of the PV strips depicted in FIG. 7

FIG. 8 illustrates in an isometric view the PV strips about a gable end portion of a roof;

FIG. 9 illustrates the PV strips about a ridge cap portion of the roof;

FIG. 10 illustrates an isometric view the PV strips about a hip cap portion of the roof;

### DETAILED DESCRIPTION OF THE PRESENT INVENTION

As required, a detailed description of the present invention is disclosed herein; however, it is to be understood that the disclosed description is merely exemplary of the invention that may be embodied in various and alternative forms. The figures are not necessarily drawn to scale. Some features may be exaggerated or minimized to show details of particular components. Therefore, specific structural and functional details disclosed herein are not to be interpreted as limiting, but merely as a representative basis for the claims and/or as a representative basis for teaching one skilled in the art to variously employ the present invention.

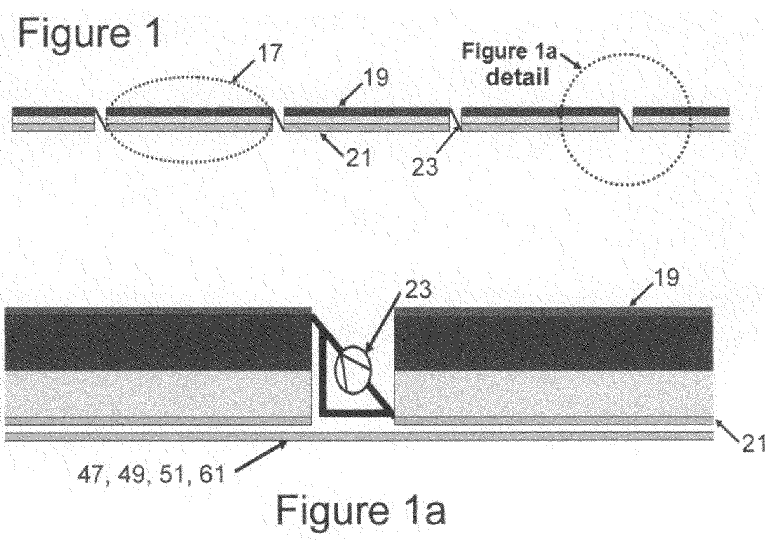

As disclosed in FIG. 1, one or more embodiments of the present disclosure will incorporate photovoltaic (PV) cells 17 that may be constructed of a thin-film semiconductor material deposited on a thin flexible substrate. The thin-film semiconductor material may include a body of substrate and electrode materials having a number of layers deposited thereon. For example, one or more embodiments of the present disclosure contemplate that the semiconductor material may be constructed of an amorphous silicon substrate (A-Si), a copper indium gallium diselenide (CIGS) substrate, and/or a cadmium telluride substrate (CdTe) and/or any other semiconductor material suitable for receiving and converting solar energy to electricity with relatively high energy efficiency.

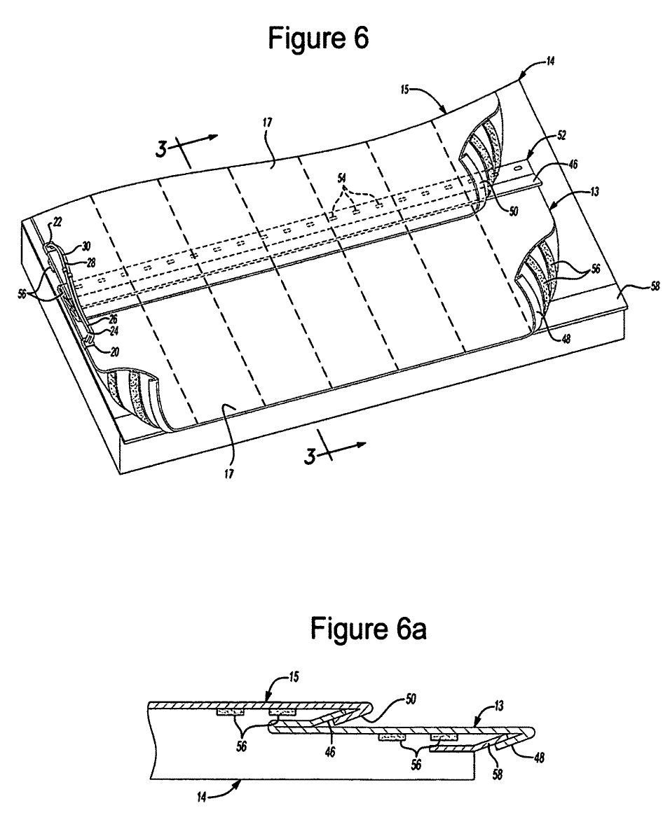

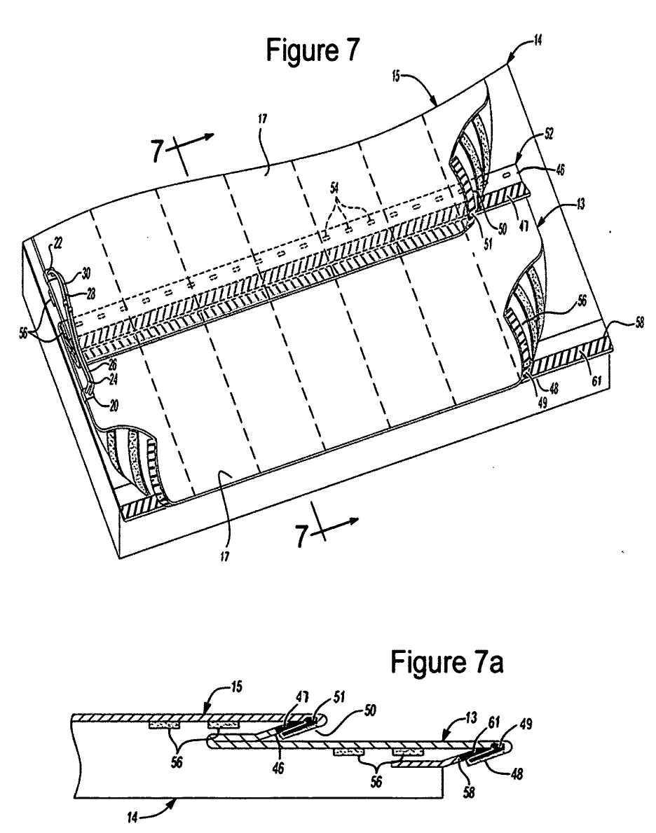

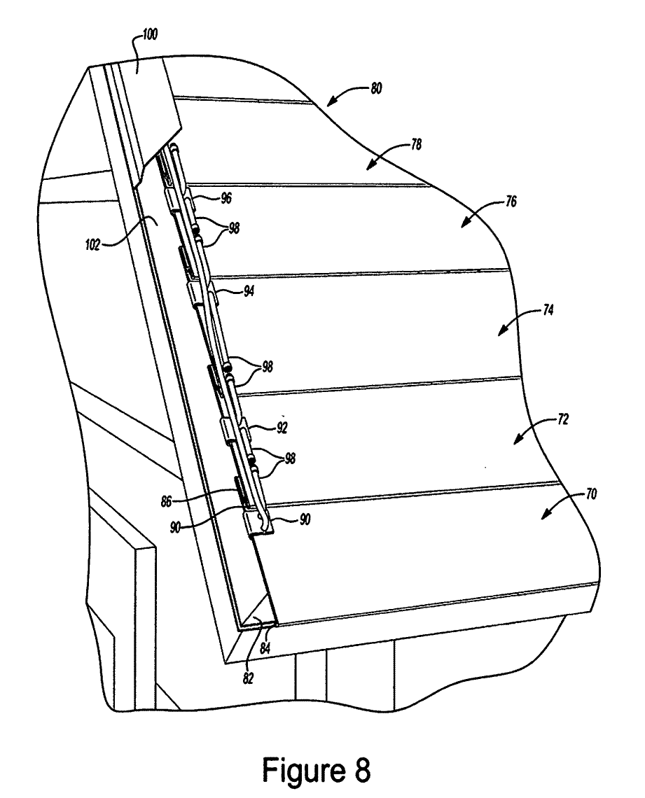

One or more embodiments of the present disclosure further contemplates that the thin and flexible PV cells 17 may be electrically connected in a series string of constant or variable amperage with voltage that increases with length. The present disclosure further contemplates that a string of PV cells 17 will be encapsulated with a clear, flexible, durable and weatherproof layer of polymeric or other material on the ‘top’ exposed side 19. The top side 19 encapsulant must be transparent to the sun's energy in order to allow solar energy to penetrate and reach the PV cells. The encapsulant used on the ‘back’ opposite side 21 must be a flexible, durable and weatherproof layer of polymeric or other material. The back side 21 encapsulant does not need to be transparent. The present disclosure contemplates that the finished encapsulated PV strip 13 and 15 as further detailed in FIGS. 6, 6a, 7, and 7a, will have a weatherproof seal that may be capable of both mechanically and electrically protecting the series string of PV cells from extreme ambient conditions.

The present disclosure further contemplates that the encapsulated PV strip 13 and 15 will be thin, flexible and in a substantially elongated configuration, such as a flattened extending strip or laminate that could be coiled on a spool. However, the present disclosure contemplates that the shape of the PV strips 13, and 15 are not limited to any specific configuration and may be designed so as to accommodate any number of surfaces, regardless of the contour or shape.

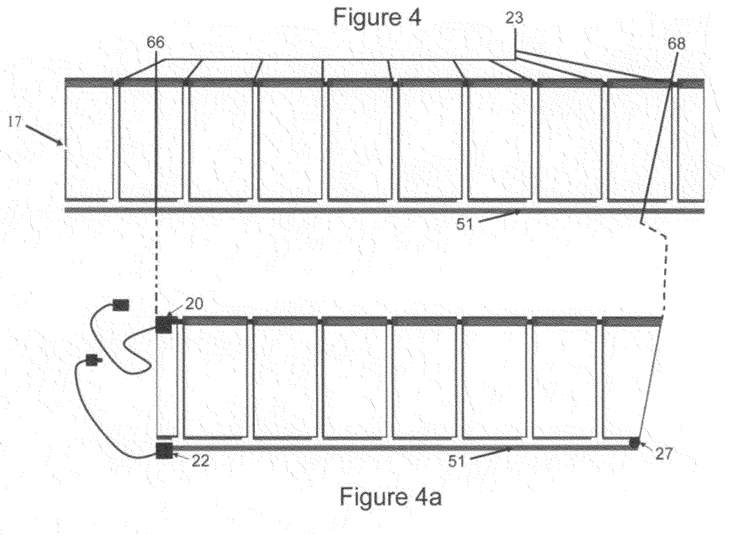

FIG. 1a shows a section through a strip of flexible thin-film PV cells 17 connected in series with bypass diodes 23 incorporated in a parallel arrangement to minimize the loss of efficiency from partial shading. The present disclosure further contemplates that at least one electrically insulated bus bar 47, 49, 51, or 61 as further detailed in FIGS. 4, 4a, 5, 7, and 7a, may run in parallel to the series string of PV cells 17, and will be encapsulated in the PV strip so as to bring the both the negative and positive conductors to the upper and lower edges, and the ends of the PV strip 13 and 15.

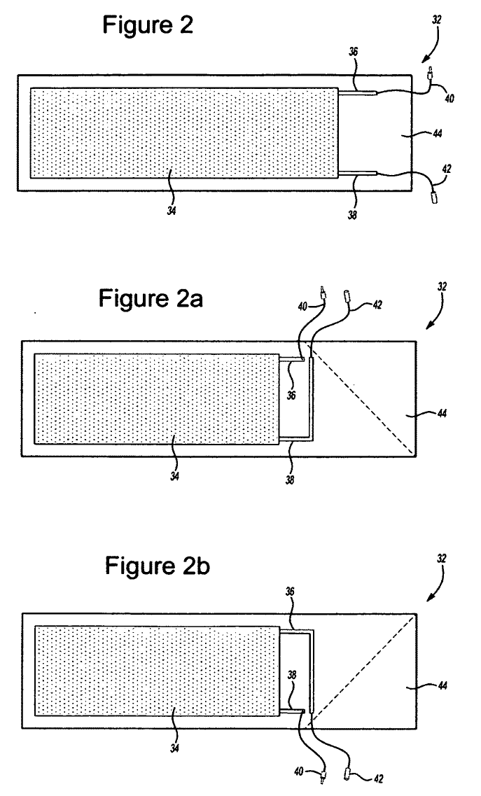

FIG. 2 further illustrates a PV strip 32, PV cells 34 and non-active material 44 which may be installed about a gable end portion of a roof. As illustrated, the PV strip 32 may include a pair of contact terminals 36, 38. While the contact terminals 36, 38 displayed in FIG. 2 are on the same side as the PV cells 34, the present disclosure contemplates that the contact terminals 36, 38 may be manufactured so as to be on the side opposite the PV cells 34. The PV strip 32 may also include a pair of quick connect cables 40, 42 electrically coupled to the contact terminals 36, 38. The present disclosure contemplates that the quick connect cables 40, 42 may be soldered, adhered, or brazed to the contact terminals 36, 38 to allow electrical connections to be made in the soffit area of the roof. Again, the quick connect cables 36, 38 may provide a quick and relatively easy connection between a plurality of PV cells, an electrical junction box, or to any other suitable electrical device.

FIGS. 2a-2b further illustrates a PV strip 32 which may be installed about a hip ridge portion of a roof. As illustrated, the active PV cells 34 may not extend completely across the entire region of the PV strip 32. By not extending substantially across the entire region, the PV strip 32 illustrated in FIGS. 2a-2b include an inactive material 44 not suitable for acquiring solar energy. The remaining non-active portion 44 may have a substantially uniform appearance with the active PV cells 34. FIGS. 2a and 2b also illustrate that the quick connect cables 40, 42 may be positioned on either edge of the active side of the PV strip 32. As such, FIGS. 2a and 2b illustrate that the inactive material 44 may be cut, and the quick connect cables 40, 42 positioned, so as to accommodate varying surfaces of a hip ridge portion of a roof.

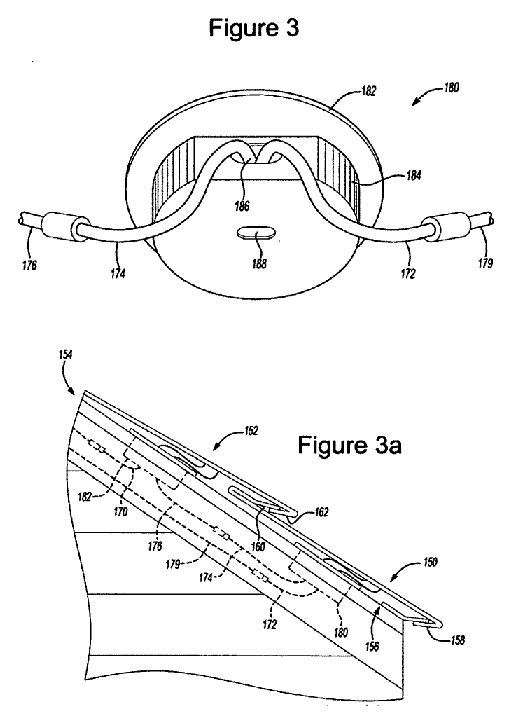

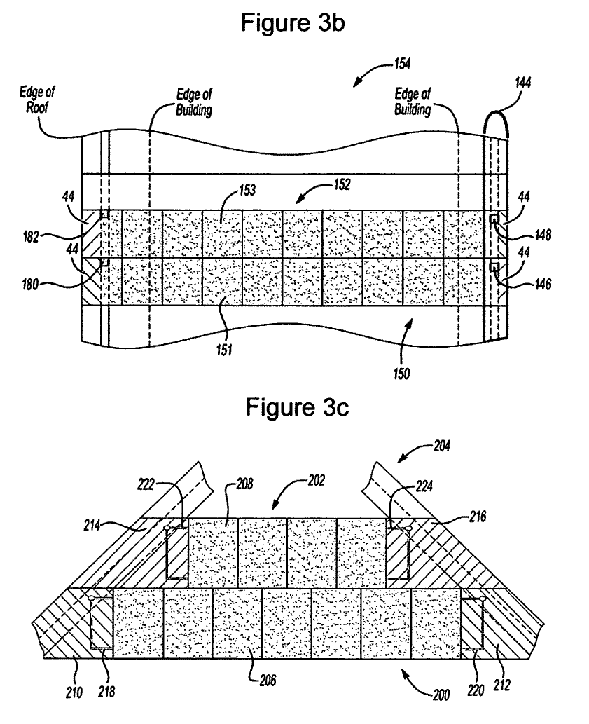

FIG. 3 illustrates a perspective view of termination cover 180. As illustrated, termination cover 180 may include a lip 182 that extends beyond a substantially spherical body 184. Furthermore, the quick connect cables 172, 174 may be fed through a hole 186 before and/or after the termination covers 180, 182 are secured to the PV strips 150, 152 as detailed in FIGS. 3a, 3b. As such, a weather resistant electrical termination may be formed between the contact terminals and the quick connect cables 172-174. In addition, the quick connect cables 172-174 may then be readily available for connection to a mating pair of quick connect cables 176, 179 which may return to another PV strip or to a combiner box, or to a battery, or to power conditioning equipment.

Lastly, the termination cover 180 may be installed so that the body extends through the drilled hole and the lip 182 rests securely upon the roof 154.

The present disclosure further contemplates that the termination cover 180 may be securely fastened to the PV strips 150, 152 using an adhesive which may be injected through a hole 188 in order to adhere the contact terminals and protect them from ambient conditions. The present disclosure contemplates that the adhesive may be epoxy glue, or any other suitable adhesive fastener.

For example, FIG. 3a illustrates a side view of the gable-end portion of the roof 154. As illustrated in FIG. 3a, a bottom drip edge 156 may be installed on, or about, the eave portion of the roof 154. The strip 150 located about the eave portion may be coupled to the bottom drip edge 156 using a bottom coupling member 158 of strip 150. Strip 152 may then be installed by coupling the top coupling member 160 of strip 150 to the bottom coupling member 162 of strip 152. Such an installation process may continue upward toward the ridge, or peak, portion of the roof 154.

As explained above with reference to FIGS. 2 through 2b, PV strips 150, 152 may be manufactured to fit the particular size and/or shape of the roof 154. For example, with reference to FIG. 3b, the PV strips 150, 152 may be manufactured to extend beyond the edge of the building and terminate at the edge of the roof 154. As such, the strips 150, 152 may not require any alteration or cuts in order to fit the particular size and/or shape of the roof.

Alternatively, strips 150, 152 may be manufactured to include one or more regions of inactive materials 44 having a substantially uniform appearance with the active PV strips. The inactive materials 44 may be used to modify the size and/or shape of the strips 150, 152. For example, if the strips 150, 152 extend beyond the edge of the roof 154, the inactive materials 44 may be cut. Because the inactive material 44 may be cut, the strips 150-152 may be manufactured to a size and/or shape which are independent of the particular size and/or shape of the roof 154.

Each strip 150, 152 may further include at least one contact terminal (not shown). As explained above with reference to FIGS. 2-2b, the contact terminals may be on the same side as the active PV cells 151, 153. However, the present disclosure also contemplates that the contact terminals may be manufactured so as to be on the side opposite the active PV cells 151, 153.

FIG. 3b illustrates a plan view of alternative methods of installing a plurality of strips 150-152 along a gable-end portion of a roof 154. Each strip 150, 152 may respectively include PV cells 151, 153. As illustrated, the roofing strips 150, 152 may be installed in a substantially horizontal fashion across the roof 154.

With reference back to FIG. 3a, each strip 150, 152 may further include one or more quick connect cables 172-179 which may be electrically coupled to the one or more contact terminals. The present disclosure contemplates that a plurality of termination covers 180, 182 may be included when the contact terminals are located on the side opposite the exposed PV cells 151, 153. The present disclosure contemplates that the termination covers 180, 182 may be used to protect each contact terminal from ambient conditions. To install each termination cover 180, 182, a hole may be drilled into the rake soffit or eave portion of the gable end of the roof 154.

Alternatively the present disclosure contemplates that a plurality of termination covers 146, 148 may be included when the contact terminals are located on the same side as the exposed PV cells 151, 153. The present disclosure contemplates that the termination covers 166, 168 may be used to protect each contact terminal from ambient conditions and covered with a removable gable end trim cap 144.

FIG. 3c illustrates a plan view of a method of installing a plurality of PV strips 200, 202 about a hip-ridge portion of a roof 204. Each strip 200, 202 may respectively include PV cells 206, 208. As illustrated, the strips 200, 202 may be installed in a substantially horizontal fashion across the roof 204.

As explained above with reference to FIGS. 2-2b, roofing strips 32 may be manufactured to fit the particular size and/or shape of the roof 204. As is shown in FIG. 3c, as the strips 200, 202 progress toward the ridge, or peak, of the roof 204, the photovoltaic material 206, 208 of each respective strip 200, 202 may decrease in size and or shape. As such, the strips 200, 202 may not require any alteration or cuts in order to fit the particular size and/or shape of the roof.

In addition, each strip 200, 202 may be manufactured to include one or more regions of inactive material 210-216 having a substantially uniform appearance with the PV cells 206, 208. The inactive materials 210-216 may be used to modify the size and/or shape of the strips 200, 202. For example, if the strips 200, 202 extend beyond the hip-ridge portion of the roof 204, the inactive materials 210-216 may be cut. Because the inactive material 210-216 may be cut, the roofing strips 200, 202 may be manufactured to a size and/or shape which are independent of the particular size and/or shape of the roof 204.

Each roofing strip 200, 202 may further include at least one contact terminal 218-224. As explained above with reference to FIGS. 2-2b, the contact terminals 218-224 may be on the same side as the PV cells 206, 208 and may be concealed under a hip ridge cap.

Each roofing strip 200, 202 may further include one or more quick connect cables (not shown) which may be electrically coupled to the one or more contact terminals 218-224. The quick connect cables may be used to electrically connect the roofing strips 200, 202 to another PV strip or an electrical junction box.

FIG. 4 shows a plan view of a strip of flexible thin-film PV cells 17 connected in series with a plurality of bypass diodes in parallel 23 and a negative buss bar 51 as disclosed in FIGS. 1 and 1a.

FIG. 4a shows a plan view of PV Cells 17 depicted in FIG. 4 after the strip of PV Cells 17 has been cut to fit a given structure across cut lines 66 and 68. Electrical bus bar clamp 27 can be installed on site to make an electrical connection with a parallel buss bar which allows both ends of the circuit to be at one end of the PV strip with wiring clamp connections 20, 22 installed on site.

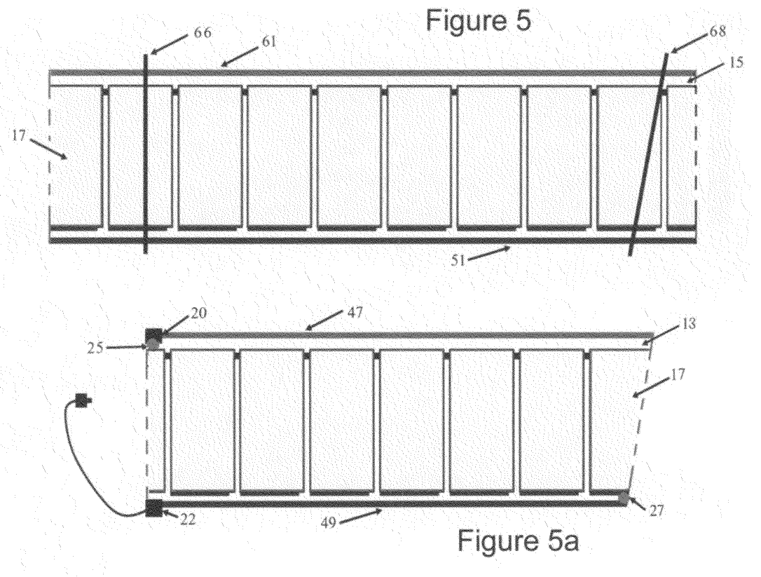

FIGS. 5 and 5a illustrate a series string of PV cells 17 in accordance with the present invention as detailed in FIGS. 4 and 4a, with the addition of a positive buss bar 47 or 61—which may be identical devices, but are given different numbers for clarification in the sequential assemblies detailed in FIGS. 7 and 7a. Continuous electrical contact elements 61, 51, 47, and 49 are depicted parallel with, and mounted above and below said PV cells 17. When the strip 15, and the bonded PV cells 17 are cut to fit a given roof along cut lines 66 and 68, electrical bus bar clamps 25 and 27 are installed to complete an electrical circuit at any desired point between any contact elements 61, 51, 47, and 49 and any PV cells 17. Bus bar clamps 25 and 27 are affixed in a manner substantially similar to wiring clamps 20 and 22. Upper electrical contact element 61 is shown as integrated with PV strip 15 and may be coupled to the lower continuous electrical contact element 49 of another roofing strip 13 as detailed in FIG. 5a in an actual installation.

The PV system in accordance with the present invention is intended to allow any number of PV strips 13 and 15 to be electrically coupled together through combinations of integrated continuous electrical contact elements 61, 51, 47, 57 and 49, bus bars 25 and 27, and clamps 20 and 22.

In FIGS. 6 and 6a, an exemplary first and second PV strips 13 and 15 are provided. Each PV strip 13 and 15 may include a series string of PV cells 17. One or more embodiments of the present disclosure contemplate that the PV cells 17 may be encapsulated so as to be a thin, flexible and substantially elongated configuration, such as one or more flattened extending strips or laminates. However, the present disclosure contemplates that the shape of the PV strips 13 and 15 are not limited to any specific configuration and may be designed so as to accommodate any number of surfaces, regardless of the contour or shape.

FIGS. 6 and 6a further illustrate the PV strips 13 and 15 being disposed upon the surface of a roof 14. While the surface illustrated is a roof 14, one or more embodiments of the present disclosure contemplate that the surface may be a wall or any other surface where solar energy may be received by the PV strips 13 and 15. Furthermore, the present disclosure contemplates that the PV strips 13 and 15 may be disposed in a substantially horizontal position upon the roof 14.

The present FIGS. 6 and 6a disclosure further contemplates that the PV strips 13 and 15 may be manufactured for a particular roof 14 shape and size. For example, the dimensions of a roof 14 may be measured and determined prior to installation of the PV strips 13 and 15. A manufacturing facility may then receive and produce the PV strips 13 and 15 in accordance to the measured dimensions. Once constructed, the PV strips 13 and 15 may be packaged in a fashion that allows for transportation. Because the PV strips 13 and 15 are formed from thin, flexible materials, the PV strips 13 and 15 may be rolled and packaged in a cylindrical transportation container (not shown). PV strips 13 and 15 may then be safely transported to the installation site.

By determining and producing the PV strips 13 and 15 according to a specific roofs dimension, the size and amount of PV Cells 17 may be optimized thereby maximizing the amount of recoverable energy. In addition, by determining and producing, the PV strips 13 and 15 according to a specific roofs dimension, the amount of time and expense required to install the PV strips 13 and 15 may be reduced, thereby reducing the overall cost to the consumer.

Alternatively, the present disclosure contemplates that the PV strips 13 and 15 may not be manufactured according to the size and/or shape of the roof 14. Instead, the present disclosure contemplates that the PV strips 13 and 15 may be manufactured in accordance with pre-packaged sizes and/or shapes. As a result, the PV strips 13 and 15 that are pre-packaged may extend beyond one edge of the roof 14. In order to accommodate the roof 14, the PV strips 13 and 15 may be separated (i.e., cut) about or near the edge of the roof 14. Once cut, a portion of the PV Cells 17 located near the edge of the roof 14 may no longer be electrically conductive. As such, wiring clamps 20, 22 may be used to clamp to a functional (i.e., an electrically conductive) portion of the PV Cells 17 so that electrical energy may be acquired from the PV strips 13 and 15.

For example, FIG. 6 illustrates the wiring clamps 20, 22 attached to the PV strips 13 and 15. The present disclosure contemplates that each wiring clamp 20, 22 may be formed of an electrically conductive material, such as copper, and may be formed in various shapes and sizes. Each wiring clamp 20, 22 may further be electrically connected to the PV Cells 17 using an electric weld, bond, or any other suitable method for bonding the wiring clamps 20, 22 to the PV Cells 17. Once electrically connected, each wiring clamp 20, 22 may provide a connection that allows electrical energy to be acquired from the PV Cells 17.

FIG. 6 further illustrates two pairs of quick connect plugs 24, 26 and 28, 30 that are electrically coupled to each respective wiring clamp 20, 22. Each pair of quick connect cables 24, 26 and 28, 30 may provide a quick and relatively easy connection between additional photovoltaic materials, an electrical junction box, or to any other suitable electrical device.

However, the present disclosure further contemplates that the wiring clamps 20, 22 may not be required if any PV strips 13 and 15 is sized to the dimensions of the roof 14. For example, FIGS. 2, 2a, and 2b illustrate an alternative PV strip 32 that may be manufactured for the particular size and/or shape of the roof 14. As illustrated, the PV strip 32 may include active PV cells 34 that may extend almost completely across the entire length of the PV strip 32. As illustrated in FIGS. 2a and 2b, the photovoltaic strip 32 may further include anon-active portion 44 having a substantially uniform appearance with the active PV cells 34. Such a construction may allow PV strip 32 to be pre-manufactured in lengths to cover an optimum amount of roof area while the solar exposure of the active PV cells 34 is able to maximize the amount of solar energy captured.

Again in FIGS. 6 and 6a, the PV strip 13 may further include a top coupling member 46 and a bottom coupling member 48. Furthermore, the PV strip 15 may also include a top coupling member (not shown) and a bottom coupling member 50. As is illustrated, the top coupling member 46 and the bottom coupling members 48, 50 may be formed so as to be continuous, thereby spanning the entire length of the PV strips 13, 15. However, one or more embodiments of the present disclosure contemplate that the top and bottom coupling members 46 and 48, 50 may not span the entire length of the PV strips 13, 15, but may alternatively be segmented at predetermined lengths across the PV strips 13, 15.

The PV strip 15 in FIG. 6 may also include a fastening member 52 located at or around the top portion of the PV strip 13. The fastening member 52 may be formed so as to be continuous, thereby spanning the entire length of the PV strips 13, 15. However, one or more embodiments of the present disclosure contemplate that the fastening member 52 may not be continuous, but may alternatively be segmented at predetermined lengths across the PV strips 13, 15.

The fastening member 52 may further include one or more apertures 54 that may be manufactured so as to receive fasteners which securely fasten the PV strips 13 and 15 to the roof 14. One or more embodiments of the present disclosure contemplate that the apertures 54 may be designed so as to receive roofing nails, screws, or any other type of fastener suitable for fastening the PV strips 13 and 15 to the roof 14.

The PV strips 13 and 15 may also include one or more adhesive members 56 positioned on a back side of the PV strips 13 and 15 opposite the PV cells 17. One or more embodiments of the present disclosure contemplate that the one or more adhesive members 56 may be formed using an adhesive such as industrial Velcro®. As such, the adhesive members 56 may adhere to a corresponding piece of industrial Velcro® attached to the roof thereby ensuring that the PV strips 13 and 15 are securely fastened to the roof 14.

One or more embodiments of the present disclosure further contemplates that the adhesive members 56 may be formed using a bitumen material. By forming the adhesive members 56 using the bitumen material, the PV strips 13 and 15 may be securely fastened directly to the roof 14. By directly fastening the PV strips 13 and 15 to the roof 14, a weather-resistant seal may be formed thereby protecting the roof 14 from ambient conditions.

FIG. 6 also illustrates a drip edge 58 being installed onto the eave portion of the roof 14. The drip edge 58 may provide protection to the roof 14 from ambient conditions, such as rain, snow, and/or ice. Additionally, the drip edge 58 may allow coupling support to the bottom coupling member 48 of a PV strip 13.

For example, FIG. 6a illustrates a cross-sectional view of FIG. 1 taken along line 3-3. As shown in FIG. 6a, the bottom coupling member 48 of the PV strip 13 may be coupled to the drip edge 58. Furthermore, the top coupling member 46 of the PV strip 13 may be coupled to the bottom coupling member 50 of the PV strip 15. Such a coupling method may continue upwards toward the ridge, or peak, of the roof 14. By using such a coupling method, a weather-proof seal may be formed between each PV strips 13 and 15 thereby protecting the roof 14 from ambient conditions.

FIG. 7 illustrates a pair of PV roofing strips in accordance with the present invention specifically depicting continuous electrical contact elements 51, 61, 47, and 49 integrated with the coupling members 56 and 50 associated with each roofing strip 13 and 15. These continuous electrical contacts 51, 61, 47, and 49 can minimize the need for many wiring clamps 20 and 22 in many circumstances—except that there will almost always be several wiring clamps 20 and 22 to provide the voltage output of the roofing strips 13 and 15.

As an example, continuous electrical contact element 51 may be electrically connected to the positive side of energy absorbing area of PV strip 15 and bonded or otherwise integrated into coupling member 50. Another continuous electrical contact element 47 may be electrically connected to the negative energy absorbing area of PV strip 13 and integrated into coupling member 46. Another continuous electrical contact element 49 may be electrically connected to the positive energy absorbing area of PV strip 13 and integrated into coupling member 53. Another continuous electrical contact element 61 may be electrically connected to the edge of roofing strip bottom edge tie down coupling member 58. When coupling member 50 and coupling member 46 are in contact with each other, and coupling member 48 and coupling member 58 are in contact with each other an electrical connection is made that allows voltage and current to flow from photovoltaic roofing strip 15 to PV strip 13 through continuous electrical contact elements 51, 61, 47, and 49.

FIG. 7 further illustrates two pairs of quick connect plugs 24, 26 and 28, 30 that are electrically coupled to each respective wiring clamp 20, 22. Each pair of quick connect cables 24, 26 and 28, 30 may provide a quick and relatively easy connection between additional photovoltaic materials 16, an electrical junction box, or to any other suitable electrical device. Electrically active drip edge 58 may serve to secure roofing strip 13 and provide an electrical contact output for the electrical circuit formed by PV roofing strips 13 and 15 through any clamp 22.

FIG. 7a illustrates a cross-sectional view of FIG. 7 taken along line 7a-7a (Change the reference numeral in figure). As shown in FIG. 7a, when coupling member 50 and coupling member 46 are in contact with each other, and coupling member 53 and coupling member 58 are in contact with each other an electrical connection is made that allows voltage and current to flow from PV strip 15 to photovoltaic roofing strip 13 through continuous electrical contact elements 51, 47, 61, and 49.

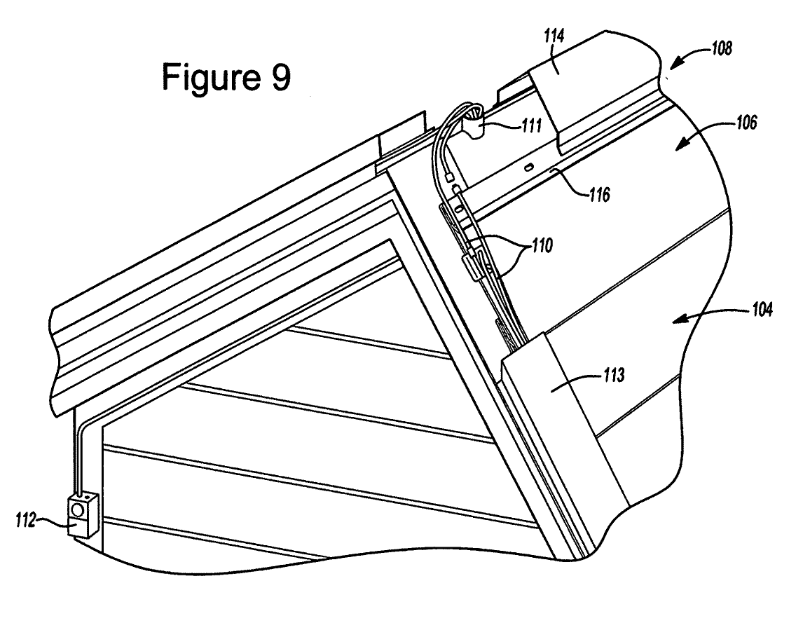

FIG. 8 illustrates in an isometric view a plurality of PV roofing strips 70-78 which may be installed along a gable-end portion of a roof 80. As illustrated, the roofing strips 70-78 may be installed in a substantially horizontal fashion across the roof 80. Furthermore, a bottom drip edge 82 may be installed on, or about, the eave portion of the roof 80.

As explained with reference to FIG. 6, each roofing strip 70-78 may be installed starting at the eave portion of the roof 80 and proceeding upwards toward the ridge, or peak, of the roof 80. For example, the roofing strip 70 located about the eave portion may be coupled to the bottom drip edge 82 using a bottom coupling member 84 of the first roofing strip 70. The second roofing strip 72 may then be installed so that the top coupling member 86 of the first roofing strip may be coupled to the bottom coupling member 90 of the roofing strip 72. Such an installation process may continue upward toward the ridge, or peak, portion of the roof 80.

FIG. 8 also illustrates a plurality of wiring clamps 90-96 attached to each respective roofing strip 70-76. Each wiring clamp 90-96 also include quick connect cables 98 attached to each respective wiring clamp 90-96. The quick connect cables 98 may be electrically connected so that the electrical energy may be acquired from each respective roofing strip 70-78.

For example, the quick connect cables 98 attached to the wiring clamp 90 of the first roofing strip 70 may be electrically connected to the quick connect cables 98 attached to the wiring clamp 92 of the second roofing strip 72. Such an electrical connection process may continue upward toward the ridge, or peak, of the roof 80.

Lastly, FIG. 8 illustrates a trim cap 100 and a side drip edge 102. The side drip edge 102 may be installed along the gable-end portion of the roof 80 and may be used to protect the roof 80 from ambient conditions. The side drip edge 102 may also provide coupling support for the trim cap 100. By coupling the trim cap 100 to the side drip edge 102, the wiring clamps 70-76 and the quick connect cables 98 may be protected from ambient conditions.

FIG. 9 illustrates a plurality of roofing strips 104, 106 installed about the ridge, or peak, portion of a roof 108. As explained above, the roofing strips may be coupled from an eave portion (not shown) of the roof 108 upward toward the ridge portion of the roof 108. As is further illustrated, the quick connect cables 110 may be electrically connected so as to be positioned along the gable end portion of the roof 108. An electrical conduit 111 may be inserted within the ridge of the roof 108. The quick connect cables 110 may then be fed through the electrical conduit 111 to a combiner box, or to a battery, or to power conditioning equipment 112.

FIG. 9 further illustrates a trim cap 113 that may be coupled along the gable end of the roof 108. As explained above the trim cap 113 may be used to protect the quick connect cables 110, and other electrical connections, from ambient conditions such as rain, snow, and ice.

In addition, FIG. 9 illustrates a ridge cap 114 which may be used to protect the quick connect cables 110 and other electrical connections located near or about the ridge portion of the roof 108 from ambient conditions such as rain, snow, and ice. The ridge cap 114 may be coupled to a top coupling member 116 of the roofing strip 106 located near, or about, the ridge portion of the roof 108.

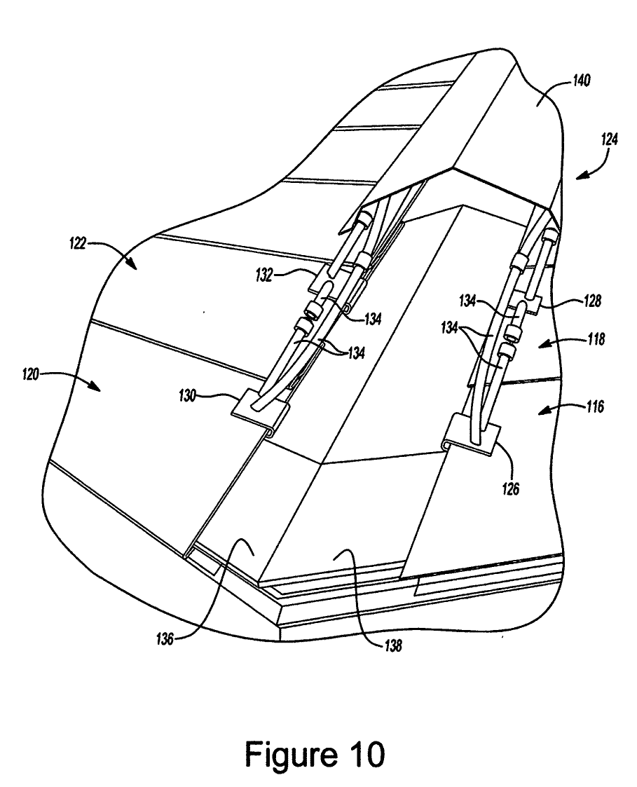

FIG. 10 illustrates a plurality of PV strips 116-122 installed about a hip ridge portion of a roof 124. Again, a plurality of wiring clamps 126-132 may be attached to each respective roofing strip 116-132. Each wiring clamp 126-132 may also include quick connect cables 134. As explained above, the quick connect cables 134 may be used to electrically connect each PV strip 116-122.

FIG. 10 further illustrates that a pair of lower drip edges 136, 138 may be installed about the eave portion of the roof 124. The PV strips 116, 120 located about the eave portion may be coupled to the lower drip edges 136, 138 in order to protect the roof 124 from ambient conditions such as rain, snow, and ice.

FIG. 10 further illustrates a hip cap 140 which may be coupled to the PV strips 116-122 about the hip portion of the roof 124. The hip cap 140 may be installed so as to protect the wiring clamps 126-132 and the quick connect cables 134 from ambient conditions.

While embodiments of the invention have been illustrated and described, it is not intended that these embodiments illustrate and describe all possible forms of the invention. Rather, the words used in the specification are words of description rather than limitation, and various changes may be made without departing from the spirit and scope of the invention.

What is claimed is:

1. A method for providing a photovoltaic (PV) material for installation upon a surface of a building, the method comprising:
providing at least one first PV strip and at least one second PV strip which include elongated strings of thin, flexible PV cells, wherein each of said at least one first PV strip and said at least one second PV strip may be cut after being manufactured to any length that will cover any portion of a surface of a structure;
providing at least one first electrically active region at least one first location on said at least one first PV strip;
providing at least one second electrically active region at least one second location on said at least one second PV strip;
fastening said at least one first PV strip upon said surface of a structure;
fastening said at least one second PV strip upon said surface of a structure in an aligned relationship with said at least one first PV strip, the at least one second PV strip being fastened so that a portion of the at least one first PV strip lies parallel to, and partially underneath, or in an otherwise weather tight manner, along a length of the at least one second PV strip.

2. The method of claim 1, wherein at least one first wiring clamp is connected to said at least one first electrically active region and wherein at least one second wiring clamp is connected to said at least one second electrically active region of said at least one first and at least one second PV strip.

3. The method of claim 2, wherein at least one first electrical cable may be connected to said at least one first wiring clamp, and wherein at least one second electrical cable may be connected to said at least one second wiring clamp.

4. The method of claim 3, wherein said at least one electrical cable is electrically connected to said at least one second electrical cable, or to a combiner box, or to a battery, or to power conditioning equipment.

5. The method of claim 1, wherein at least one weather-proof cap is coupled to said surface of a structure, said weather proof cap protecting said at least one wiring clamp, said at least one second wiring clamp, said at least one first electrical cable, and said at least one second electrical cable from ambient conditions.

6. The method of claim 4, further comprising establishing said electrical connection at any region of a building surface including an eave region, a ridge region, an endwall region, a hip region, a soffit region, a gable end region, or a sidewall region of a building structure or a building roof.

7. The method of claim 1, wherein said at least one first PV strip and said at least one second PV strip are manufactured to a predetermined length so as to cover a predetermined section of a building surface, and each PV strip further includes at least one electrical connector coupled to a string of thin, flexible PV cells.

8. The method of claim 1, wherein said PV strips may include in part or in total an inactive material having a substantially similar appearance to the active region of the photovoltaic material.

9. The method of claim 1, wherein an electrical connection is made directly between said at least one first electrically active region at said at least one first location on said at least one first PV strip and at least one second electrically active region at said at least one second location on said at least one second PV strip.

10. A photovoltaic (PV) system comprising:
at least one first PV strip and at least one second PV strip which include elongated portions of thin, flexible PV cells wherein each of said at least one first PV strip and said at least one second PV strip may be cut after being manufactured to any length that will cover any portion of a surface of a structure;
at least one first electrically active region at least one first location on said at least one first PV strip;
at least one second electrically active region at least one second location on said at least one second PV strip;
at least one first fastening member incorporated into said at least one first PV strip and at least one second fastening member incorporated into said at least one second PV strip such that said at least one second PV strip and said at least one first PV strip may be fastened upon said surface of a structure in an aligned relationship such that a portion of said at least one first PV strip lies parallel to, and partially underneath, or in an otherwise weather tight manner, along a length of said at least one second PV strip.

11. The system of claim 10 further comprising at least one first wiring clamp connected to said at least one first electrically active region of said at least one first PV strip, and at least one second wiring clamp connected to said at least one second electrically active region of said at least one second PV strip.

12. The system of claim 11 further comprising at least one first electrical cable that is connected to said at least one first wiring clamp, and least one second electrical cable that is connected to said at least one second wiring clamp wherein said at least one first electrical cable is electrically connected to said at least one second electrical cable, or a combiner box, or a battery, or power conditioning equipment.

13. The system of claim 10 further comprising a direct electrical connection that is made between said at least one first electrically active region of said at least one first PV strip and said at least one second electrically active region of said at least one second PV strip when said at least one first PV strip and said at least one second PV strip are fastened to said surface of a structure.

14. The system of claim 12 further comprising at least one weather-proof cap that is coupled to the surface of a structure, said at least one weather proof cap protecting said electrical connection from ambient conditions.

15. The system of claim 11, wherein each PV strip may include in part or in total an inactive material having a substantially similar appearance to the active region of the photovoltaic material.
